(19) United States
(12) Patent Application Publication
(10) Pub. No.: US 2018/0046228 A1
(43) Pub. Date: Feb. 15, 2018

(54) ENCLOSURE MOUNTING AND TRANSPORTATION PLATFORM

(71) Applicant: CommScope Technologies LLC, Hickory, NC (US)

(72) Inventors: Charles J. Mann, Omaha, NE (US); Darin W. Piburn, Keller, TX (US)

(21) Appl. No.: 15/668,042

(22) Filed: Aug. 3, 2017

Related U.S. Application Data
(60) Provisional application No. 62/373,795, filed on Aug. 11, 2016.
(60) Provisional application No. 62/416,925, filed on Nov. 3, 2016.

(51) Int. Cl. G06F 1/18; H05K 7/18; H05K 7/14

(52) U.S. Cl. CPC G06F 1/181; H05K 7/1497; H05K 7/186; G06F 1/1656

(57) ABSTRACT

A method of shipping and installing an enclosure, comprising the steps of: (a) mounting an enclosure on a platform; (b) shipping the enclosure mounted on the platform to a remote location and (c) installing the platform and enclosure at the remote location.

### RELATED APPLICATION

The present application claims priority from and the benefit of U.S. Provisional Patent Application No. 62/373,795, filed Aug. 11, 2016, and U.S. Provisional Application No. 62/416,925, filed Nov. 3, 2016, the disclosure of each of which is hereby incorporated herein in its entirety.

### FIELD OF THE INVENTION

The present invention is directed to enclosures, and more particularly to the shipping and mounting of enclosures.

### BACKGROUND

Outdoor network enclosures are used widely throughout telecommunications and other network applications. They can protect a wide range of electronic equipment including radios, multicarrier power amplifiers (MCPA), power supplies, batteries, and wireless cell site backhaul equipment. These cabinets can protect base station equipment from environmental conditions while minimizing operating expenses and energy consumption.

Installation methods for outdoor enclosures vary. Techniques may involve pour-on-site concrete platforms, pre-cast concrete platforms, direct bury pedestals, and other mounting solutions.

Packaging for shipping these outdoor enclosures typically involves mounting the product to a pallet formed of wood or other materials. The pallet is typically is disposed of once the product arrives on the customer's site.

### SUMMARY

As a first aspect, embodiments of the invention are directed to a method of shipping and installing an enclosure. The method comprises the steps of: (a) mounting an enclosure on a platform; (b) shipping the enclosure mounted on the platform to a remote location; and (c) installing the platform and enclosure at the remote location. Use of the platform as both a shipping pallet and an installation platform can reduce cost and waste.

As a second aspect, embodiments of the invention are directed to an integrated enclosure and platform, comprising: an enclosure; and a platform, the enclosure secured to the platform for shipping, the platform including features configured to enable the platform to be mounted in the ground on site.

In some embodiments, an anchor is employed to mount the platform and enclosure in the ground. In some embodiments, the anchor is a pad or vault, which may include features that receive conduit that is subsequently routed to the enclosure.

### BRIEF DESCRIPTION OF THE FIGURES

FIG. 1 is a perspective view of a platform according to embodiments of the invention.

FIG. 2 is a perspective view of a helical anchor to be used with the platform of FIG. 1.

FIG. 3 is a perspective view of a locking bar to be used with the platform of FIG. 1.

FIG. 4 is a perspective view of a main retainer bracket to be used with the platform of FIG. 1.

FIG. 5 is a perspective view of the platform of FIG. 1 with an enclosure mounted thereon.

FIG. 6 is a perspective view of the platform and enclosure of FIG. 5 along with accessories packaged for shipping.

FIG. 7 is a perspective view of a deployment site for the platform and enclosure of FIG. 1.

FIG. 8 is a perspective view of the helical anchor of FIG. 2 and the main retainer bracket of FIG. 4 mounted on the deployment site of FIG. 7.

FIG. 9 is a perspective view of the enclosure and platform of FIG. 5 being mounted on the deployment site of FIG. 8.

FIG. 10 is a perspective section view of the platform and deployment site of FIG. 5 with the enclosure removed for clarity.

FIG. 11 is a perspective view of the installed platform and enclosure of FIG. 9 with side and end panels added.

FIG. 12 is a perspective view of a cabinet and platform or pallet mounted to an underground vault according to embodiments of the invention.

FIG. 13 is a perspective view of the vault of FIG. 12 illustrating a support frame mounted thereon and the routing of cable ducts.

FIG. 14 is an exploded view of the vault, support frame and cable ducts of FIG. 13.

FIG. 15 is a perspective view of a cabinet and platform or pallet mounted to an underground pad according to embodiments of the invention.

FIG. 16 is a perspective view of the pad of FIG. 15 illustrating the routing of cable ducts.

FIG. 17 is an exploded view of the pad of FIG. 16.

FIG. 18 is a front view of the cabinet, pallet, support frame, vault, and cable ducts of FIGS. 12 and 13.

FIG. 19 is a front view of the cabinet, pallet, pad and cable ducts of FIGS. 15 and 16.

### DETAILED DESCRIPTION

Aspects of the present disclosure are described more fully hereinafter with reference to the accompanying drawings, in which embodiments of the present disclosure are shown. The presented disclosure however, be embodied in many different forms and should not be construed as limited to the embodiments set forth herein; rather, these embodiments are provided so that this disclosure will be thorough and complete, and will fully convey the scope of the present disclosure to those skilled in the art.

Like numbers refer to like elements throughout. In the figures, the thickness of certain lines, layers, components, elements or features may be exaggerated for clarity.

The terminology used herein is for the purpose of describing particular embodiments only and is not intended to be limiting of the present disclosure. Unless otherwise defined, all terms (including technical and scientific terms) used herein have the same meaning as commonly understood by one of ordinary skill in the art to which this present disclosure belongs. It will be further understood that terms, such as those defined in commonly used dictionaries, should be interpreted as having a meaning that is consistent with their meaning in the context of the specification and relevant art and should not be interpreted in an idealized or overly formal sense unless expressly so defined herein. Well-known functions or constructions may not be described in detail for brevity and/or clarity.

As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof As used herein, the term “and/or” includes any and all combinations of one or more of the associated listed items. As used herein, phrases such as “between X and Y” and “between about X and Y” should he interpreted to include X and Y. As used herein, phrases such as “between about X and Y” mean “between about X and about Y.” As used herein, phrases such as “from about X to Y” mean “from about X to about Y.”

It will be understood that when an element is referred to as being “on”, “attached” to, “connected” to, “coupled” with, “contacting”, etc., another element, it can be directly on, attached to, connected to, coupled with or contacting the other element or intervening elements may also be present. In contrast, when an element is referred to as being, for example, “directly on”, “directly attached” to, “directly connected” to, “directly coupled” with or “directly contacting” another element, there are no intervening elements present. It will also be appreciated by those of skill in the art that references to a structure or feature that is disposed “adjacent” another feature may have portions that overlap or underlie the adjacent feature.

Spatially relative terms, such as “under”, “below”, “lower”, “over”, “upper”, “lateral”, “left”, “right” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is inverted, elements described as “under” or “beneath” other elements or features would then be oriented “over” the other elements or features. The device may be otherwise oriented (rotated 90 degrees or at other orientations) and the descriptors of relative spatial relationships used herein interpreted accordingly.

Embodiments of the present invention may be directed to a concept that involves the creation of a single device, such as a platform or pallet, to accomplish both shipping and mounting of enclosures, and in particular telecommunications enclosures. In some embodiments, the enclosure may be shipped and delivered on this multi-purpose platform, then installed on site using the same device. The platform should be a durable, environmentally stable platform structure, which is large enough compared to the applied enclosure to provide a stable transportation device. As discussed below, this platform may include details that allow the enclosure to be attached, either via typical hardware, or perhaps with detail features that allow the enclosure to interlock with the surface of the platform. Also, shock absorbing features may be included into the platform assembly, either via secondary accessories, or built into the structure of the platform (i.e. crush or crumble zones within the material of the platform).

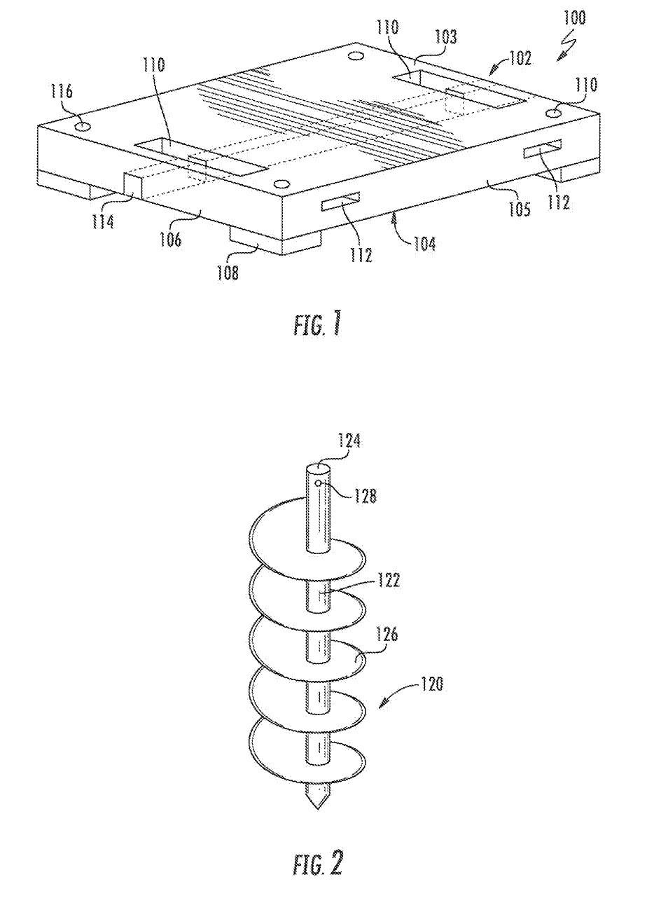

Referring now to the drawings, FIG. 1 illustrates an exemplary platform, designated broadly at 100, that may be used for both shipping and mounting of a telecommunications enclosure. The platform 108 includes a generally rectangular main panel 102 that is typically horizontally disposed. The main panel 102 has an upper surface 103, a lower surface 104, two opposed side surfaces 105, and two opposed end surfaces 106. Four feet 108 support the underside of the main panel 102 at the corners. In some embodiments, the feet 108 may be formed of a shock-absorbing material to provide shock absorption for the platform 100. The platform 100 typically has a “footprint” of at least 3 feet×4 feet, and is typically between about 4 and 6 inches in thickness.

As can be seen in FIG. 1, the platform 100 includes a number of openings to facilitate use of the platform 100. Two conduit slots 110 extend between the upper and lower surfaces 103, 104. Two locking bar slots 112 extend between the side surfaces 105 and pass through the conduit slots 110. A main retainer slot 114 extends between the end surfaces 106 and is open to the lower surface 104; the main retainer slot 114 passes through the conduit slots 110 and intersects with the locking bar slots 112. Four vertical anchoring holes 116 are located near the corners of the main panel 102.

The platform 100 should be formed of a material that provides strength, resilience, resistance to environmental elements, and the like. Exemplary materials for the platform 100 include polymeric materials such as polypropylene, polyethylene, and polystyrene, any of which may be provided in solid form or as a structural foam.

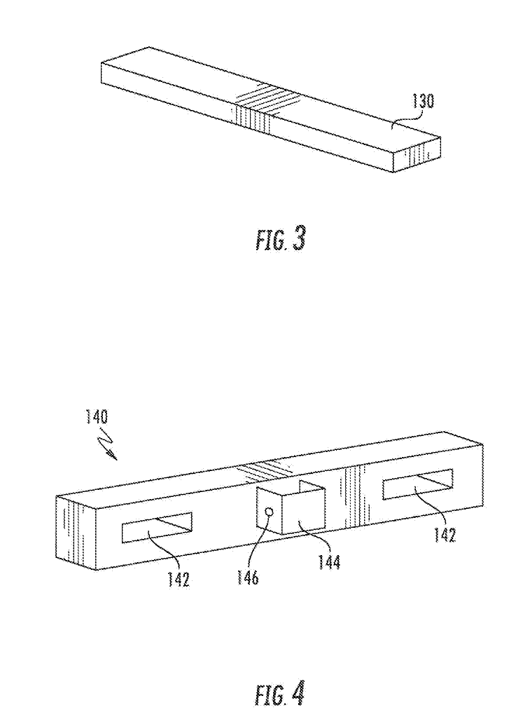

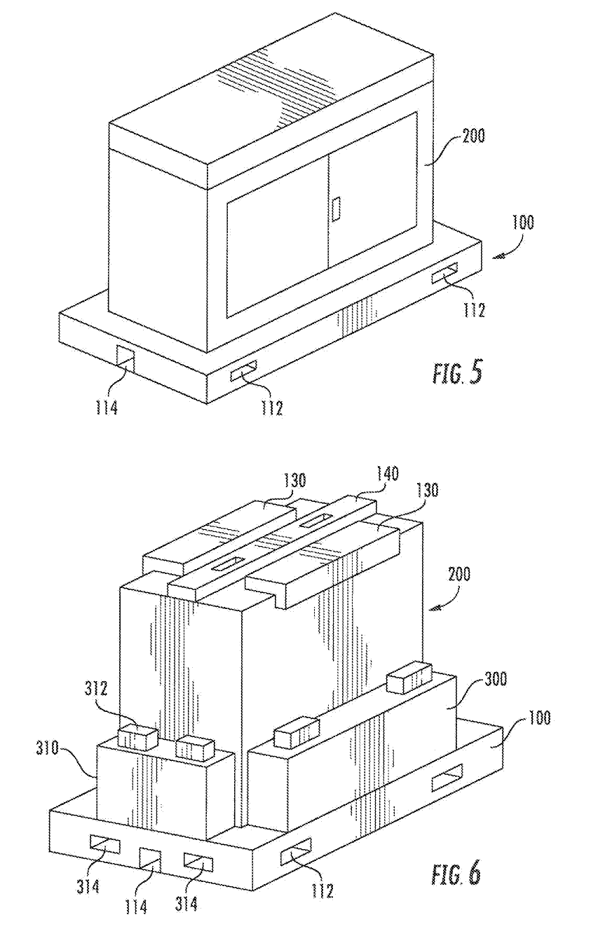

FIGS. 2-4 illustrate additional components used to secure the platform 100 in place. FIG. 2 shows a helical anchor 120 with a shaft 122 having a square top end 124 and a blade 126 that follows a helical path around and along the shaft 122. A hole 128 extends through the top end 124. FIG. 3 shows one of two elongate locking bars 130 of rectangular cross-section. FIG. 4 illustrates a main retainer bracket 140. The main retainer bracket 140 is elongate and rectangular in cross-section. Two slots 142 are present near the ends of the main retainer bracket 140 and are sized to receive the locking bars 130. A C-shaped bracket 144 extends horizontally from the center of the main retainer bracket 140; two holes 146 are located on opposite sides of the C-shaped bracket 144.

As can be seen in FIG. 5, the platform 100 underlies an attached enclosure 200. The enclosure 200 may be any typical enclosure used to house telecommunications or other equipment; exemplary enclosures are shown, for example, in U.S. Provisional Patent Application No. 62/311,589, filed Mar. 22, 2016, the disclosure of Which is hereby incorporate herein in its entirety. in the illustrated embodiment, the enclosure 200 is attached to the platform 100 via anchoring fasteners (not shown) that are inserted into the anchoring holes 116. However, those of skill in this art will recognize that many other securing configurations may be suitable, including those in which the enclosure 200 includes features that mate with or otherwise engage features in the platform 100.

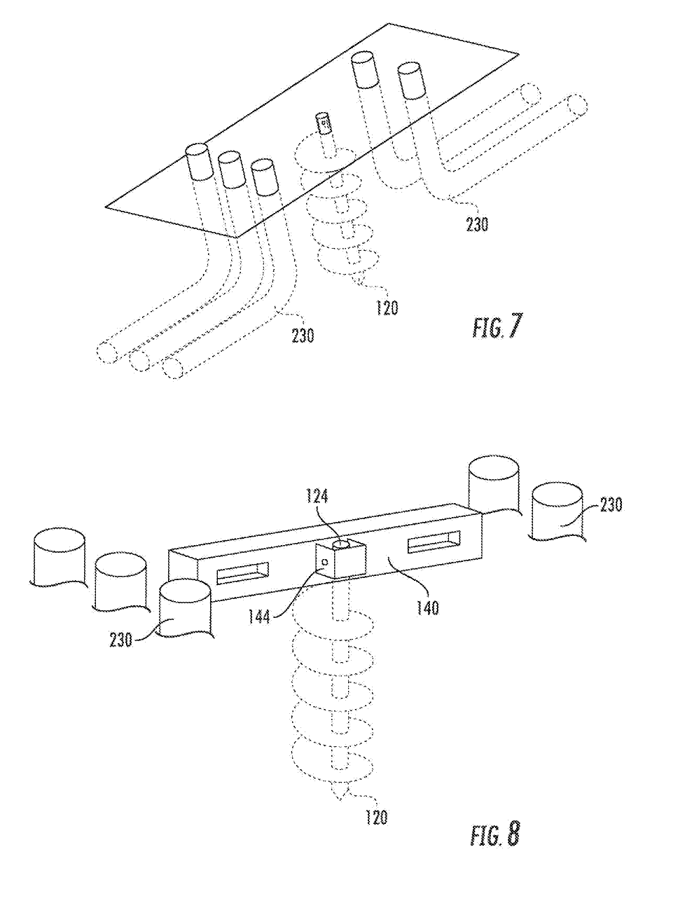

It is anticipated that, in sonic embodiments, the platform 100 will replace a shipping pallet for the enclosure 200, such that the platform 100 and enclosure 200 are shipped together as a single integrated unit from the factory to the deployment site. As shown in FIG. 6, additional components of the system may he employed during shipping to serve as buffers, shock absorbers and the like. For example, the locking bars 130 and the main retainer bracket 140 may be positioned on the top of the enclosure 200, and accessory platform panels 300, 310 (described in greater detail below) may be positioned to protect portions of the sides of the enclosure 200.

Once delivered to the deployment site, the integrated enclosure 200 and platform 100 would remain assembled, and placed directly on the customer's site. The platform 100 may replace the traditional concrete or metal platform or plinth, and is permanently used as the mounting platform.

Installation of the enclosure 200 and platform 100 are discussed below. Outdoor enclosures typically require an anchor system to stabilize the enclosure, to prevent accidental toppling of the enclosure. The mounting structure must meet requirements for impact and atmospheric conditions, such as high wind speeds. Also, typically the enclosure 200 is connected to incoming underground conduits that provide power, signals, and the like, so installation of the platform 100 should consider this need also.

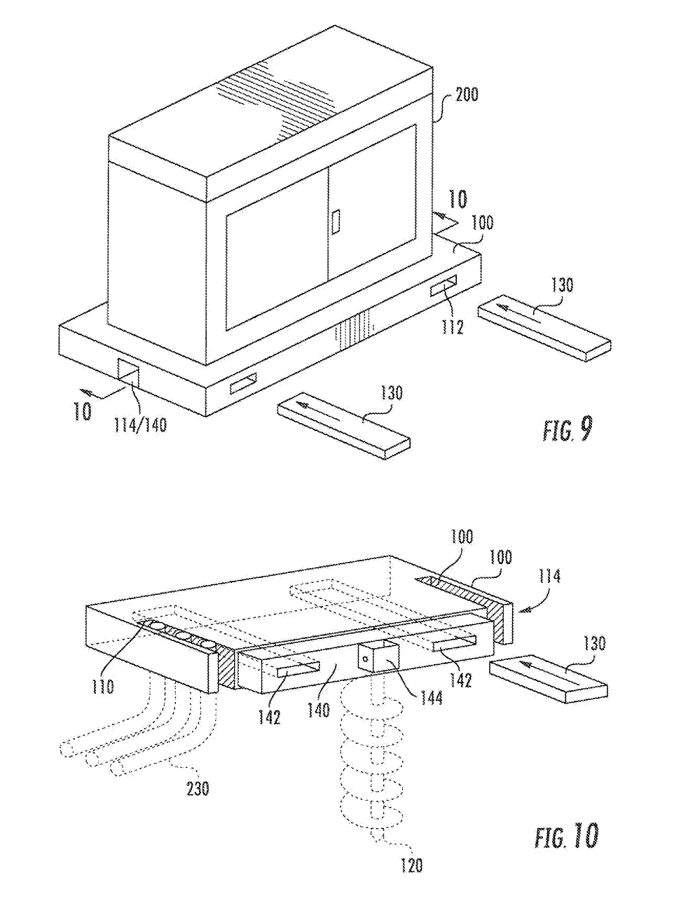

Referring now to FIG. 7, installation of the enclosure 200 begins with the preparation of the site. This may include the rough grading of the site along with the installation of the aforementioned underground conduits (designated herein at 230). The helical anchor 120, employed to provide stability, is also driven into the ground. Both the conduits 230 and the helical anchor 120 are located in pre-defined positions that align with, respectively, the anticipated locations of the conduit slots 110 and the C-shaped bracket 144 of the main retainer bracket 140. In some embodiments, insertion of the helical anchor 120 may be followed by mechanical resistance measurements to assure that the anchor provides a desired level of retention regardless of soil conditions. Although a helical anchor 120 is shown herein, it is recognized that a variety of alternative anchoring members may be suitable, including straight rods or stakes driven to an appropriate depth, either manually or mechanically inserted into the earth.

Once the helical anchor 120 is secured, the main retainer bracket 140 is installed (see FIG. 8). The main retainer bracket 140 is used to connect the anchor 120 to the platform 100 and can provide a stable, above-grade attachment point for the platform 108. The top end 124 of the helical anchor 120 is inserted into the C-shaped bracket 144 of the main retainer bracket 140. Pins, bolts or the like are inserted into the holes 146 of the C-shaped bracket 144 and the holes 128 in the top end of 124 of the helical anchor 120 to secure the main retainer bracket 140 to the helical anchor 120. It should also be noted that, in some embodiments, the anchor and the main retainer bracket may be formed as a single component.

The platform 100 and enclosure 200 are then moved into place on the site (see FIGS. 9 and 10). The main retainer bracket 140 is positioned in the main retainer slot 114, and the conduits 230 are routed through the conduit slots 110. The locking bars 130 are fully inserted into the locking bar slots 112 in the side surfaces 105 of the main panel 102 and through the slots 142 in the main retainer bracket 140. Through this action, the locking bars 130 lock the platform 100 to the main retainer bracket 140, which in turn fixes the platform 100 relative to the ground via the helical anchor 120.

Notably, the use of the illustrated configuration enables independent anchor installation, and allows the platform 100 to remain connected to the enclosure 200 during installation. Also, the arrangement allows the shaft 122 and blade 126 of the helical anchor 120 to be positioned below grade, the main retainer bracket 140 to be above grade, and the enclosure/platform unit 100, 200 to be positioned above grade, all while retaining access underground via the locking bars 130 and the main retainer bracket 140.

Once the locking bars 130 have been installed, the integrated enclosure/platform unit 100, 200 is securely attached to the helical anchor 120. Final details may be added to cosmetically secure the platform 100. Also, final grading around the platform 100 may be conducted once the locking bars 130 are installed.

Referring now to FIG. 11, it is also anticipated that accessory components could be added to the system, primarily to add work surfaces outside the perimeter of the enclosure. For example, side panel 300 may be added to the side of the platform 100 by inserting stubs 302 into the locking bar slots 112. Similarly, end panel 310 can be added to the end of the platform 100 by inserting a stub 312 into the main retainer slot 114, or into additional optional slots 314 on the end of the platform 100. The addition of the work surfaces provided by the side and end panels 300, 310 can allow the platform size to be optimized for transportation and still provide adequate work platforms outside the perimeter of the enclosure 200. For example, some enclosures have door swings that are equivalent to the depth of the enclosure, and these work accessory components could be added to allow the platform 100 to be expanded to include this door swing area. The accessories may be attached to the main platform via mechanical fasteners, or through details/features in the platform that allow direct connection between components.

As discussed above and as shown in FIG. 6, it is anticipated that the main retainer bracket 140, the locking bars 130, and the side and end panels 300, 310 may be utilized as part of the protective packing details for shipment, replacing traditional cardboard or foam packing details. As such, this system may essentially eliminate all traditional packaging components, other than perhaps an exterior carton or plastic film wrap.

The use of the integrated transportation and mounting platform may reduce or eliminate the need for the traditional mounting pad or platform. In addition, labor savings are anticipated by avoiding the need to remove the enclosure from the packing material and transferring it to the traditional concrete pad.

The mounting platforms discussed above may be installed in the ground as discussed above, or may be installed with anchoring components that facilitate the routing and connection of conduits 230. Referring now to FIGS. 12-14 and 18, an anchoring vault for supporting a platform, designated broadly at 400, is shown therein. The vault 400 includes two side walls 402, two end walls 404, and a skeletal support frame 406 that form a box-like structure. Both the side walls 402 and end walls 404 are shown as comprising an open grid, but any or all of these components may be solid. The side walls 404 include notches 405 in their lower edges to receive conduits 230. The end walls 402 and end walls 404 may be formed of a polymeric material. The frame 406, which is typically formed of a metallic material, rests on ledges 402a, 404a attire upper edges of the side and end wails 402, 404. The frame 406 includes holes 407 at either end to receive conduits.

As can be seen in FIG. 18, the vault 400 is installed below ground. As can be seen in FIGS. 13 and 14, conduits 230 are routed from outside of the vault 400 inwardly through the notches 405, then upwardly through the holes 407 to enter the platform 100. The platform 100 can be mounted to the frame 406 through fasteners 412 or other means, or in some embodiments by use of locking bars and the like, as described above.

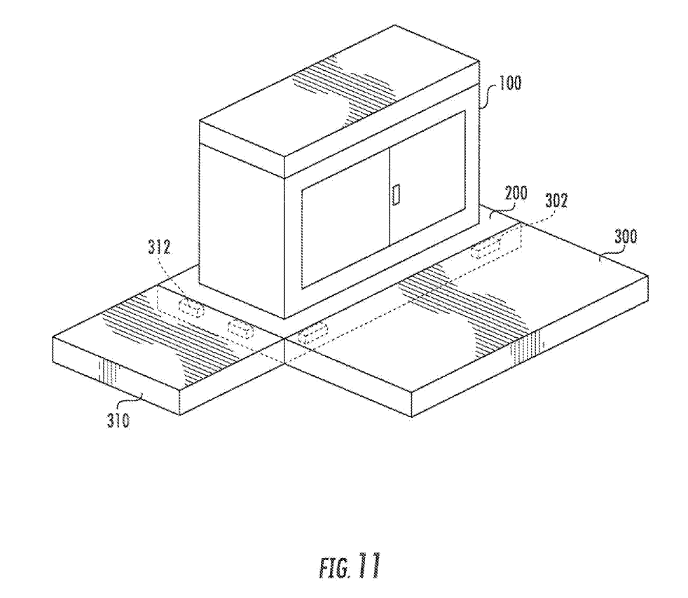

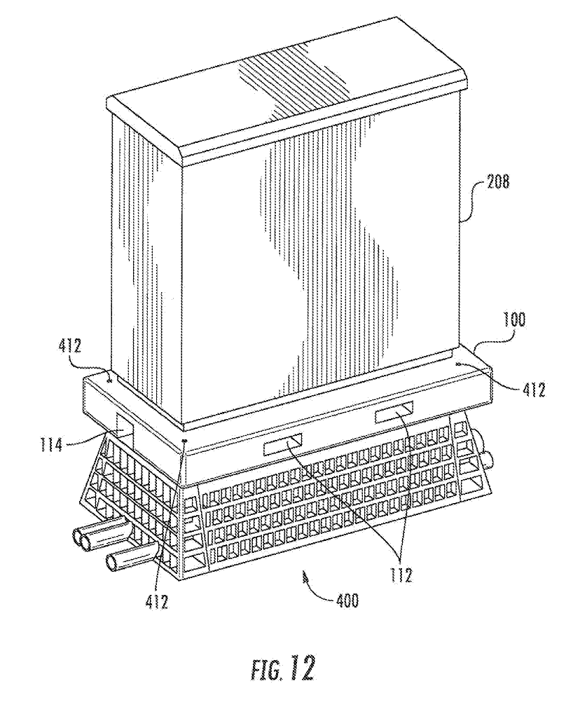

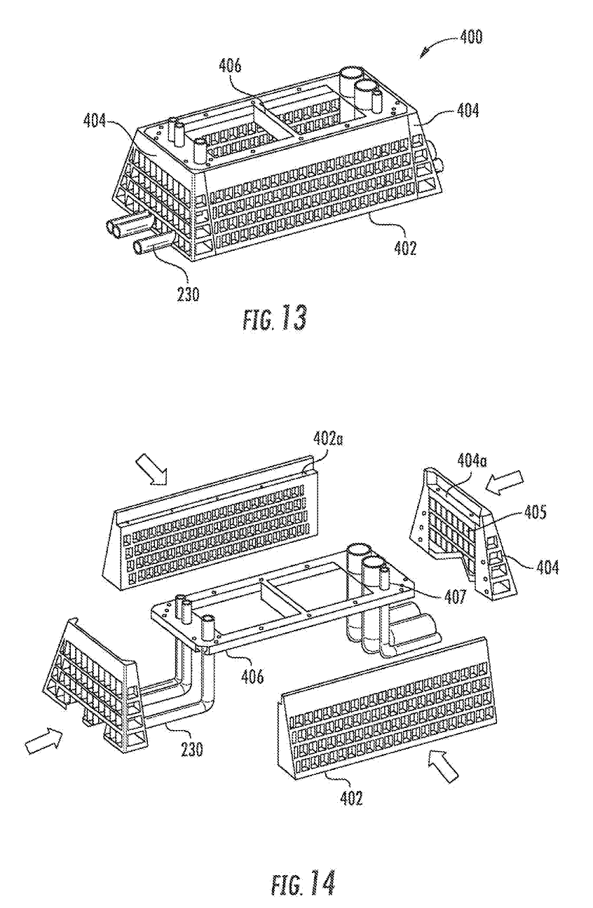

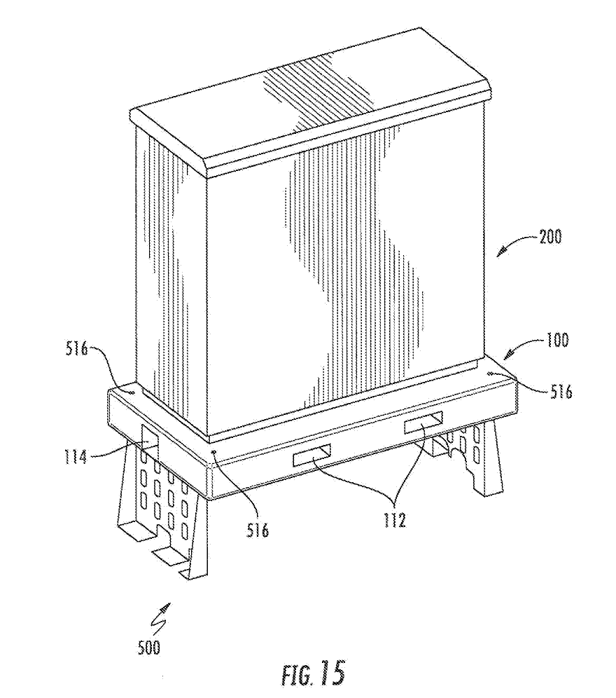

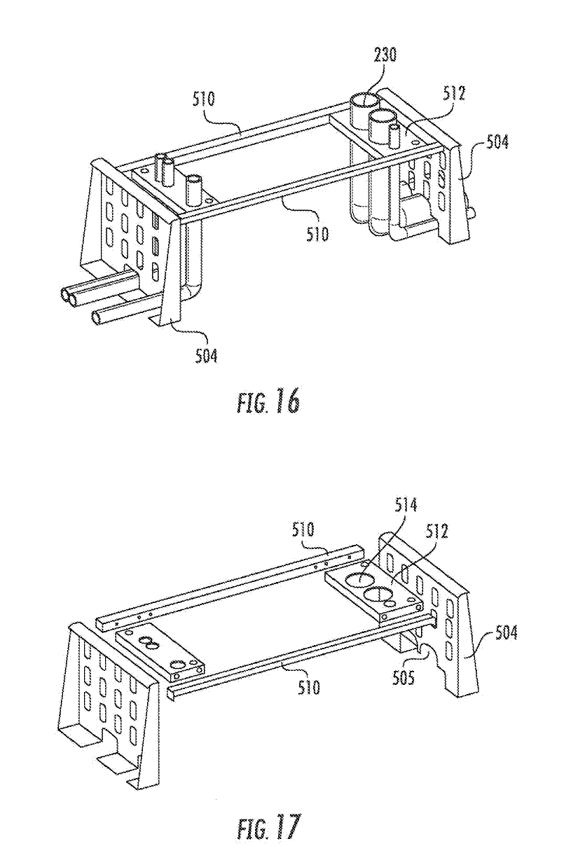

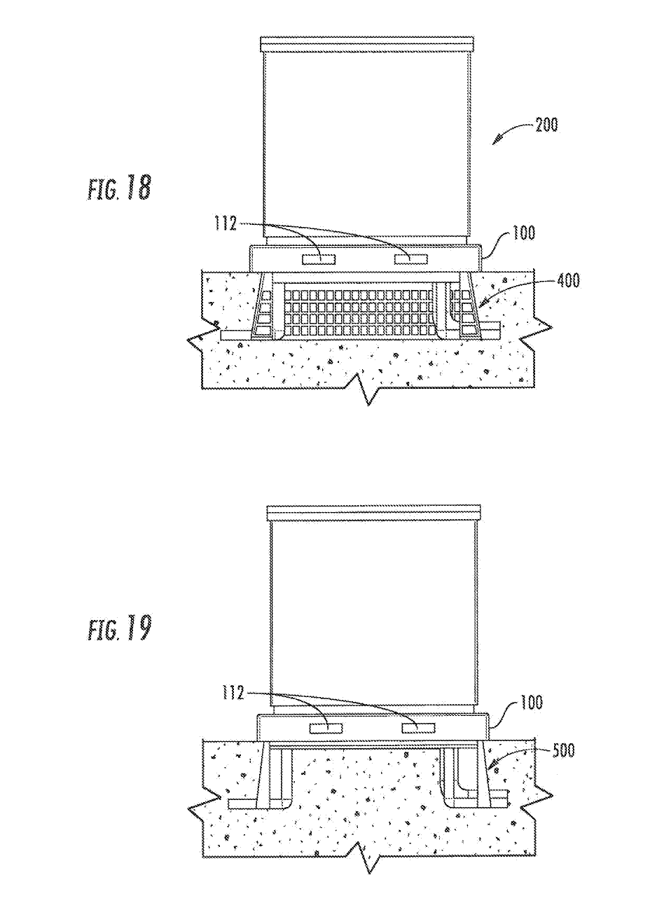

An alternative installation technique is shown in FIGS. 15-17 and 19, which illustrate an anchoring pad 500. The anchoring pad 500 includes two end wails 504 with notches 505 in their lower edges. Rails 510 span the upper ends of the end walls 504. A bracket 512 with holes 514 is mounted between the rails 510 near the end walls 504. The end walls 504, rails 510 and brackets 512 are typically formed of a metallic material.

As can be seen in FIG. 16, conduits 230 can he routed from outside the mounting pad 500 through the notches 505 in the end walls 504, then upwardly through the holes 514. From there the conduits 230 can he routed through the platform 100 and into the cabinet 200. The platform 100 is mounted to the rails 510 via fasteners 516 or other means.

The foregoing is illustrative of the present invention and is not to be construed as limiting thereof. Although exemplary embodiments of this invention have been described, those skilled in the art will readily appreciate that many modifications are possible in the exemplary embodiments without materially departing from the novel teachings and advantages of this invention. Accordingly, all such modifications are intended to be included within the scope of this invention as defined in the claims. The invention is defined by the following claims, with equivalents of the claims to be included therein.

That which is claimed is:

1. A method of shipping and installing an enclosure, comprising the steps of:
(a) mounting an enclosure on a platform;
(b) shipping the enclosure mounted on the platform to a remote location; and
(c) installing the platform and enclosure at the remote location.

2. The method defined in claim 1, wherein step (c) includes: inserting an anchor into the ground at the remote location; and attaching the platform to the anchor.

3. The method defined in claim 2, wherein the attaching step is carried out with the enclosure mounted on the platform.

4. method defined in claim 2, wherein a main retainer bracket is attached to the anchor and to the platform during step (c).

5. The method defined in claim 4, wherein the main retainer bracket is above ground, and the anchor is at least partially below ground.

6. The method defined in claim 1, further comprising the step of routing underground conduit through openings in the platform.

7. The method defined in claim 1, wherein the enclosure is a telecommunications enclosure.

8. The method defined in claim 1, wherein the platform has a footprint of at least 3 feet×4 feet.

9. The method defined in claim 1, wherein the platform includes shock absorbing features.

10. The method defined in claim 1, farther comprising the step of attaching an accessory panel to the platform to increase working surface area of the platform.

11. An integrated enclosure and platform, comprising:
an enclosure;
a platform, the enclosure secured to the platform for shipping, the platform including features configured to enable the platform to be mounted in the ground on site.

12. The integrated enclosure and platform defined in claim 11, wherein the enclosure is a telecommunications enclosure.

13. The integrated enclosure and platform defined in claim 11, further comprising packaging material wrapped onto the enclosure.

14. The integrated enclosure and platform defined in claim 13, further comprising accessories packaged therewith.

15. The integrated enclosure and platform defined in claim 11 mounted on an installation site with an anchor.

16. The integrated enclosure and platform defined in claim 15, wherein the anchor is inserted at least partially underground, the platform is above ground, and a retaining member that is above ground engages both the anchor and the platform.

17. The integrated enclosure and platform defined in claim 16, wherein the retaining member resides within an open slot in the platform, and further comprising locking members that lock the retaining member to the platform.

18. The integrated enclosure and platform of claim 15, wherein the anchor is an underground anchoring vault, and the features of the platform are configured for mounting to the underground anchoring vault.

19. The integrated enclosure and platform of claim 15, wherein anchor is an underground anchoring pad, and the features of the platform are configured for mounting on the underground anchoring pad.

20. The integrated enclosure of claim 15, wherein the anchor includes notches for receiving underground conduit routed to the platform.

21. The integrated enclosure of claim 15, wherein the anchor defines a cavity below the platform to facilitate the routing of conduit from underground into the enclosure.
